(19) United States
(12) Patent Application Publication
(10) Pub. No.: US 2012/0206998 A1
(43) Pub. Date: Aug. 16, 2012

(54) ANODIC BONDING APPARATUS, METHOD OF MANUFACTURING PACKAGE, PIEZOELECTRIC VIBRATOR, OSCILLATOR, ELECTRONIC APPARATUS, AND RADIO TIMEPIECE

(76) Inventors: Masashi Numata, Chiba-shi (JP); Kazuyoshi Sugama, Chiba-shi (JP)

(21) Appl. No.: 13/361,115

(22) Filed: Jan. 30, 2012

(30) Foreign Application Priority Data
Feb. 10, 2011 (JP) 2011-027879

(51) Int. Cl. H01L 41/053; C09J 5/00; B29C 65/18; H03B 5/36; G04C 11/02

(52) U.S. Cl. 368/47; 310/344; 331/158; 156/499; 156/322

(57) ABSTRACT

An anodic bonding apparatus includes a first intermediate member that is disposed between an upper surface (an outer surface) of a lead substrate wafer and a first heater, has heat conductivity, and can be flexible; and a second intermediate member that is disposed between a lower surface (an outer surface) of a base substrate wafer and a second heater, has conductivity and heat conductivity, and can be flexible, wherein the first intermediate member is formed so that a central portion thereof bulges toward the base substrate wafer further than a periphery portion thereof, and the second intermediate member is formed so that a central portion thereof bulges toward the lead substrate wafer further than a periphery portion thereof, and, the first intermediate member and the second intermediate member are evenly deformed.

### RELATED APPLICATIONS

This application claims priority under 35 U.S.C. §119 to Japanese Patent Application No. 2011-027879 filed on Feb. 10, 2011, the entire content of which is hereby incorporated by reference.

### BACKGROUND OF THE INVENTION

1. Field of the Invention

The present invention relates to an anodic bonding apparatus, a method of manufacturing packages using the anodic bonding apparatus, a piezoelectric vibrator manufactured by the use of the method of manufacturing the package, an oscillator, an electronic apparatus, and a radio timepiece.

2. Description of the Related Art

For example, in a mobile phone or a portable digital assistant, a piezoelectric vibrator is used which uses crystal or the like as a time source or a timing source of a control signal or the like, a reference signal source or the like. As this type of piezoelectric vibrator, various types are known, but as one of them, a surface mount type piezoelectric vibrator of a two-layer structure type is known.

This type of piezoelectric vibrator is packaged by the bonding of a first substrate and a second substrate, and a piezoelectric vibrating reed is received in a cavity formed between both of the substrates. The first substrate and the second substrate are heated and anodically bonded so that the temperature (hereinafter, referred to as a “bonding temperature”) of each substrate is about 250° C. to 300 C in vacuum or in an inert gas via a bonding material such as aluminum or silicon (for example, see JP-A-2001-72433).

Herein, generally, the first substrate and the second substrate are generally formed of a glass material, and the glass material contains organic matter, moisture or the like.

Particularly, when baking a glass frit to form a penetration electrode passing through the inside and the outside of the package, there is a fear that an organic solvent will remain in the glass frit after the baking. For this reason, when heating the respective substrates during anodic bonding, there is a fear that the glass materials of the respective substrates, the organic matter, moisture or the like in the glass frit will be generated as out gases.

Furthermore, it is preferable that the piezoelectric vibrator suppresses an equivalent resistance value (an effective resistance value, Re) to a low value. Generally, it is known that, as the inner portion of the package with the piezoelectric vibrating reed sealed therein is closer to vacuum, the equivalent resistance value is suppressed to a low level. Thus, there is a need to perform the anodic bonding while effectively discharging the out gases generated from the respective substrates to the outside of the package.

However, since the inner surfaces of the first substrate and the second substrate are anodic bonding surfaces, the inner surfaces are polished. For this reason, in the inner surfaces and the outer surfaces of the first substrate and the second substrate, the outer surface of a rough surface has a surface area wider than the inner surface of a smooth surface. Thus, upon performing the anodic bonding, when heating the respective substrates up to the bonding temperature, the inner surfaces of the first substrate and the second substrate are dented, whereby the respective substrates are greatly warped.

Moreover, when performing the anodic bonding so as to align the inner surfaces of the respective substrates in the state in which the inner surfaces are dented and the respective substrates are warped, peripheries of the respective substrates firstly come into close-contact with each other, and the anodic bonding proceeds from the periphery portion toward the central portion. As a result, there is a fear that the out gas generated from the respective substrates will not be discharged out of the package but sealed in the package, making it difficult to ensure a satisfactory degree of vacuum in the package.

Thus, an object of the present invention is to provide an anodic bonding apparatus that can ensure a satisfactory degree of vacuum in the package, a method of manufacturing the package using the anodic bonding apparatus, a piezoelectric vibrator manufactured by the method of manufacturing the package, an oscillator having the piezoelectric vibrator, an electronic apparatus, and a radio timepiece.

### SUMMARY OF THE INVENTION

In order to solve the problem, according to the present invention, there is provided an anodic bonding apparatus for manufacturing a package by anodically bonding an inner surface of a first substrate and an inner surface of a second substrate via a bonding material, the apparatus includes a first heater that is disposed at an outer surface side of the first substrate and presses the first substrate during anodic bonding; a second heater that is disposed at an outer surface side of the second substrate and presses the second substrate during anodic bonding; a first intermediate member that is disposed between the outer surface of the first substrate and the first heater, has heat conductivity, and can be flexible; and a second intermediate member that is disposed between the outer surface of the second substrate and the second heater, has conductivity and heat conductivity, and can be flexible, wherein the first intermediate member is formed so that a central portion thereof bulges toward the second substrate further than a periphery portion thereof, the second intermediate member is formed so that a central portion thereof bulges toward the first substrate further than a periphery portion thereof, and, as the respective heaters press the corresponding substrates, respectively, the respective intermediate members are evenly deformed.

According to the present invention, since the first intermediate member is configured such that the central portion bulges toward the second substrate further than the periphery portion and the second intermediate member is configured such that the central portion bulges toward the first substrate further than the periphery portion, immediately after the anodic bonding is started, the bonding load can act on the central portions of the first substrate and the second substrate to firstly anodically bond the central portion. Furthermore, since the first intermediate member and the second intermediate member are evenly deformed during anodic bonding, after anodically bonding the central portions of the first substrate and the second substrate, it is possible to sequentially perform the anodic bonding in a concentric circular shape toward the periphery portions of the first substrate and the second substrate. As a result, even when force attempting to dent and warp the inner surface is generated in the first substrate and the second substrate, it is possible to perform the anodic bonding while effectively discharging the out gas without sealing the out gas. Thus, it is possible to ensure a satisfactory degree of vacuum in the package.

Furthermore, the first intermediate member and the second intermediate member may be formed of porous carbon.

According to the present invention, since the first intermediate member and the second intermediate member can ensure the satisfactory conductivity and heat conductivity, reliable anodic bonding can be performed. Furthermore, by forming the first intermediate member and the second intermediate member by the porous material, during anodic bonding, the first intermediate member and the second intermediate member can reliably and evenly be deformed. Thus, it is possible to cause the bonding load to act on the whole inner surfaces of the first substrate and the second substrate and reliably perform the anodic bonding.

Furthermore, the bonding material may be silicon.

According to the present invention, by using silicon as the bonding material, a package having excellent corrosion resistance can be formed. Furthermore, since the out gas can effectively be discharged during anodic bonding, it is preferable to use silicon, which generates gas during anodic bonding, as the bonding material.

Furthermore, in the middle of the second heater, a penetration hole may be formed through which the inner surface and the outer surface of the second heater communicate with each other, and a pin member may be inserted into the penetration hole so as to press the second intermediate member from the outer surface side toward the inner surface side during anodic bonding.

According to the present invention, by pressing the second intermediate member from the outer surface side toward the inner surface side by the pin member, large bonding load can be caused to act in the central portions of the first substrate and the second substrate, thereby performing the anodic bonding. Thus, after anodically bonding the central portions of the first substrate and the second substrate, the anodic bonding can be reliably and sequentially performed toward the periphery portions of the first substrate and the second substrate. As a result, even when force attempting to dent and warp the inner surface is generated in the first substrate and the second substrate, the anodic bonding can reliably be performed while effectively discharging the out gas without sealing the out gas. Thus, it is possible to ensure a more satisfactory degree of vacuum in the package.

Furthermore, according to the present invention, there is provided a method of manufacturing a package by the use of the anodic bonding apparatus mentioned above, the method includes a setting and preheating process of setting the first substrate on the first heater via the first intermediate member, setting the second substrate on the second heater via the second intermediate member, and preliminarily heating the first substrate and the second substrate; and an anodic bonding process of pressing the first intermediate member toward the second substrate, pressing the second intermediate member toward the first substrate, evenly deforming the first intermediate member and the second intermediate member, and bonding the first substrate and the second substrate.

According to the present invention, by having the setting and preheating process of setting and preliminarily heating the first substrate and the second substrate, it is possible to discharge the out gas from the first substrate and the second substrate in advance. Furthermore, in the anodic bonding process, since the first intermediate member configured such that the central portion bulges toward the second substrate further than the periphery portion and the second intermediate member configured such that the central portion bulges toward the first substrate further than the periphery portion are used, immediately after the anodic bonding is started, it is possible to cause the bonding load to act on the central portions of the first substrate and the second substrate, thereby anodically bonding the central portions in advance. In addition, in the anodic bonding process, since the first intermediate member and the second intermediate member are evenly deformed, after anodically bonding the central portions of the first substrate and the second substrate, the anodic bonding can sequentially be performed in a concentric circular shape toward the periphery portions of the first substrate and the second substrate. As a result, even when force attempting to dent and warp the inner surface is generated in the first substrate and the second substrate, the anodic bonding can be performed while effectively discharging the out gas without sealing the out gas. Thus, it is possible to ensure a more satisfactory degree of vacuum in the package.

Furthermore, according to the present invention, there is provided a piezoelectric vibrator which is configured so that a piezoelectric vibrating reed is sealed in an inner portion of the package manufactured by the method of manufacturing the package.

According to the present invention, since the piezoelectric vibrating reed is sealed in the inner portion of the package manufactured by the method of manufacturing the package capable of ensuring a satisfactory degree of vacuum, it is possible to provide a piezoelectric vibrator that has a low equivalent resistance value and excellent electrical characteristics.

Furthermore, according to the preset invention, there is provided an oscillator which is configured so that the piezoelectric vibrator is electrically connected to an integrated circuit as an oscillating element.

Furthermore, according to the preset invention, there is provided an electronic apparatus which is configured so that the piezoelectric vibrator is electrically connected to a count portion.

Furthermore, according to the preset invention, there is provided a radio timepiece which is configured so that the piezoelectric vibrator is electrically connected to a filter portion.

According to the oscillator, the electronic apparatus and the radio timepiece of the present invention, since the piezoelectric vibrator having the low equivalent resistance value and the excellent electrical characteristics is included, it is possible to provide a high-performance oscillator, electronic apparatus, and radio timepiece.

According to the present invention, since the first intermediate member is configured so that the central portion bulges toward the second substrate further than the periphery portion, and the second intermediate member is configured so that the central portion bulges toward the first substrate further than the periphery portion, immediately after the anodic bonding is started, it is possible to cause the bonding load to act on the central portions of the first substrate and the second substrate, thereby anodically bonding the central portions in advance. Furthermore, since the first intermediate member and the second intermediate member are evenly deformed during anodic bonding, after anodically bonding the central portions of the first substrate and the second substrate, it is possible to sequentially perform the anodic bonding in the concentric circular shape toward the periphery portions of the first substrate and the second substrate. As a result, even when force attempting to dent and warp the inner surface is generated in the first substrate and the second substrate, the anodic bonding can be performed while effectively discharging the out gas without sealing the out gas. Thus, it is possible to ensure a satisfactory degree of vacuum in the package.

### BRIEF DESCRIPTION OF THE DRAWINGS

FIG. 1 is an exterior perspective view that shows a piezoelectric vibrator.

FIG. 2 is a plan view that shows an internal configuration of the piezoelectric vibrator shown in FIG. 1 in the state of detaching a lead substrate.

FIG. 3 is a cross-sectional view in lines A-A of FIG. 2.

FIG. 4 is an exploded perspective view of the piezoelectric vibrator shown in FIG. 1.

FIG. 5 is a flow chart of a method of manufacturing the piezoelectric vibrator.

FIG. 6 is an exploded perspective view of a wafer body.

FIG. 7 is an explanatory diagram of an anodic bonding device.

FIG. 8 is a cross-sectional view of a first intermediate member and a second intermediate member in the anodic bonding apparatus.

FIG. 9 is an explanatory diagram of an anodic bonding process.

FIG. 10 is a configuration diagram that shows an embodiment of an oscillator.

FIG. 11 is a configuration diagram that shows an embodiment of an electronic apparatus.

FIG. 12 is a configuration diagram that shows an embodiment of a radio timepiece.

### DETAILED DESCRIPTION OF THE PREFERRED EMBODIMENTS

Hereinafter, a piezoelectric vibrator according to an embodiment of the present invention will be described with reference to the drawings.

In the description mentioned below, a first substrate is described as a lead substrate (or a lead substrate wafer), and a second substrate is described as a base substrate (or a base substrate wafer). Furthermore, a bonding surface between the base substrate (or the base substrate wafer) and the lead substrate (or the lead substrate wafer) is described as an upper surface U, and an outer side surface of the base substrate (or the base substrate wafer) is described as a lower surface L.

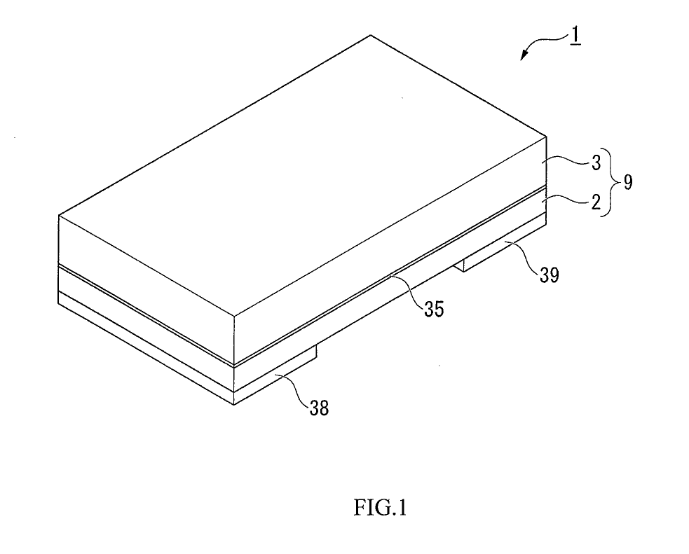

FIG. 1 is an exterior perspective view of a piezoelectric vibrator 1.

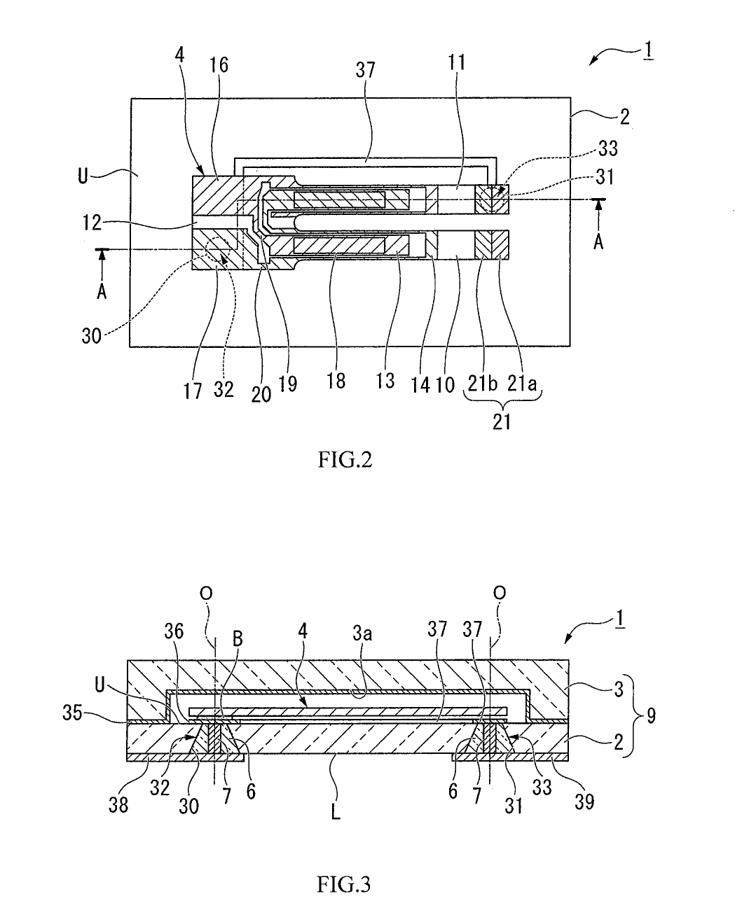

FIG. 2 is a plan view that shows an inner configuration of the piezoelectric vibrator 1 in the state of detaching a lead substrate 3.

FIG. 3 is a cross-sectional view in lines A-A of FIG. 2.

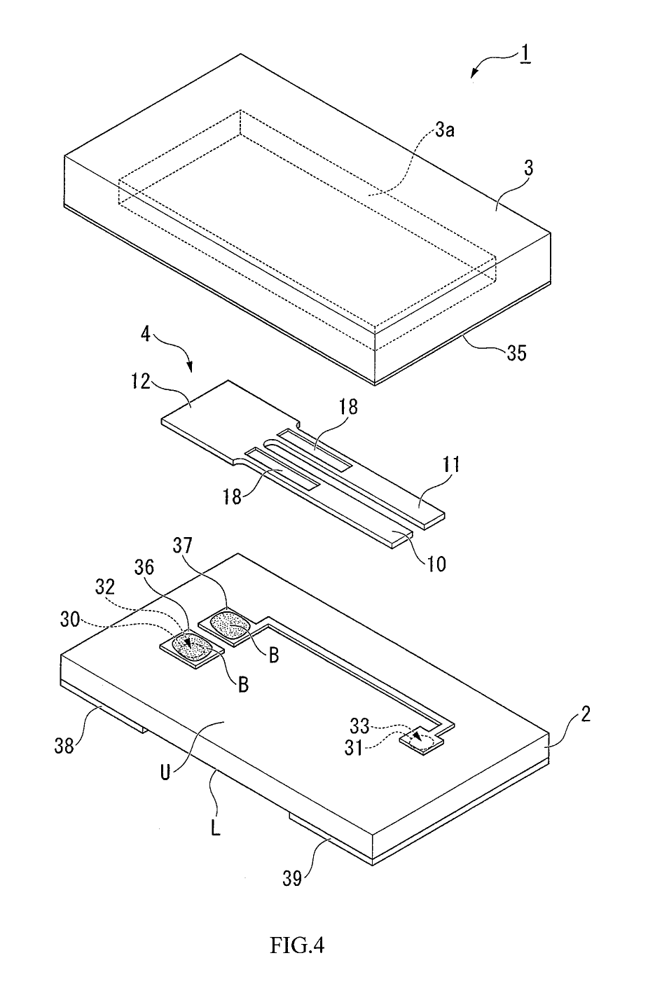

FIG. 4 is an exploded perspective view of the piezoelectric vibrator 1 shown in FIG. 1.

In addition, in FIG. 4, excitation electrodes 13 and 14 described below, drawing electrodes 19 and 20, mount electrodes 16 and 17, and a weight metal film 21 are omitted so as to clarify the drawings.

As shown in FIG. 1, the piezoelectric vibrator 1 of the present embodiment is a surface mount type piezoelectric vibrator 1 that includes a package 9 in which a base substrate 2 and a lead substrate 3 are anodically bonded to each other via a bonding film 35, and a piezoelectric vibrating reed 4 received in a cavity 3a of the package 9.

### (Piezoelectric Vibrating Reed)

As shown in FIG. 2, the piezoelectric vibrating reed 4 is a tuning fork-type vibrating reed that is formed of a piezoelectric material such as crystal, lithium tantalite, or lithium niobate, and is vibrated when a predetermined voltage is applied. The piezoelectric vibrating reed 4 includes a pair of vibration arm portions 10 and 11 disposed in parallel, a base portion 12 that integrally fixes proximal end sides of the pair of vibration arm portions 10 and 11, and groove portions 18 that are formed on both main surfaces of the pair of vibration arm portions 10 and 11. The groove portions 18 are formed from the proximal end sides of the vibration arm portions 10 and 11 up to approximately the vicinity of the intermediate along a longitudinal direction of the vibration arm portions 10 and 11.

The excitation electrodes 13 and 14 and the drawing electrodes 19 and 20 are formed with single layer films by chrome of the same material as the base layer of mount electrodes 16 and 17 described later. As a result, it is possible to form the base layers of the mount electrodes 16 and 17 and form the excitation electrodes 13 and 14 and the drawing electrodes 19 and 20.

The excitation electrodes 13 and 14 are electrodes that vibrate the pair of vibration arm portions 10 and 11 in a direction approaching and separating from each other at a predetermined resonant frequency. The first excitation electrode 13 and the second excitation electrode 14 is patterned and formed on the outer surface of the pair of vibration arm portions 10 and 11 in the state of being electrically disconnected.

The mount electrodes 16 and 17 are laminated films of chrome and gold, and are formed by forming a thin film of gold on the surface as a finishing layer after forming a chrome film having a good adhesion with crystal as a base layer.

At the tips of the pair of vibration arm portions 10 and 11, a weight metal film 21 for performing adjusting (a frequency adjustment) of the vibration state thereof so as to be vibrated within a predetermined frequency range is coated. The weight metal film 21 is divided into a rough adjustment film 21a that is used when roughly adjusting the frequency and a minute adjustment film 21b used when minutely adjusting the frequency. By performing the frequency adjustment by the use of the rough adjustment film 21a and the minute adjustment film 21b, it is possible to put the frequencies of the pair of vibration arm portions 10 and 11 within the range of the nominal frequency of the device.

### (Package)

As shown in FIG. 3, the base substrate 2 and the lead substrate 3 are an anodically bondable substrate that are formed of a glass material, for example, a soda-lime glass, and are formed in an approximate plate shape. At a bonding surface side in the lead substrate 3 with the base substrate 2, a cavity 3a is formed which receives the piezoelectric vibrating reed 4.

At the entire bonding surface side in the lead substrate 3 with the base substrate 2, a bonding film 35 (a bonding material) for the anodic bonding is formed. In addition to the entire inner surface of the cavity 3a, the bonding film 35 is formed in a frame region around the cavity 3a. The bonding film 35 of the present embodiment is formed of silicon, but it is also possible to form the bonding film 35 by aluminum, chrome or the like. As mentioned below, the bonding film 35 and the base substrate 2 are anodically bonded, whereby the cavity 3a is vacuum-sealed.

The piezoelectric vibrator 1 includes penetration electrodes 32 and 33 that penetrate the base substrate 2 in a thickness direction and make the inside of the cavity 3a and the outside of the piezoelectric vibrator 1 conductive with each other. Moreover, the penetration electrodes 32 and 33 are formed of metal pins 7 that are disposed in the penetration holes 30 and 31 penetrating the base substrate 2 and electrically connect the outside of the piezoelectric vibrating reed 4, and barrels 6 that are filled between the penetration holes 30 and 31 and the metal pins 7. In addition, the penetration electrode 32 will be described as an example below, but the same is also true for the penetration electrode 33. Furthermore, the electrical connections of the penetration electrode 33, the leading electrode 37, and the external electrode 39 are the same as those of the electrical connections of the penetration electrode 32, the leading electrode 36, and the external electrode 39.

The penetration hole 30 is formed so that an inner shape thereof is gradually increased from the upper surface U side to the lower surface L side of the base substrate 2 and so that the cross section including a central axis O of the penetration hole 30 becomes a tapered shape.

Metal pin 7 is a conductive rod-like member that is formed of a metallic material such as silver, nickel alloy, and aluminum, and is molded by the forging and the press working. For example, it is preferable that the metal pin 7 be formed of a metal having a coefficient of linear expansion closer to that of a glass material of the base substrate 2, for example, alloy (42 alloy) that contains iron of 58 weight % and nickel of 42 weight %.

The barrel 6 is made of a baked glass frit paste. In the center of the barrel 6, the metal pin 7 is disposed so as to penetrate the barrel 6, and the barrel 6 is firmly fixed to the metal pin 7 and the penetration hole 30.

As shown in FIG. 4, at the upper surface U side of the base substrate 2, a pair of leading electrodes 36 and 37 is patterned. Furthermore, on the pair of leading electrodes 36 and 37, bumps B formed of gold, respectively, are formed, and the pair of mount electrodes of the piezoelectric vibrating reed 4 is mounted by the use of the bumps B. As a result, one mount electrode 16 (see FIG. 2) of the piezoelectric vibrating reed 4 is conducted to one penetration electrode 32 via one leading electrode 36, and the other mount electrode 17 (see FIG. 2) is conducted to the other penetration electrode 33 via the other leading electrode 37.

On the lower surface L of the base substrate 2, a pair of external electrodes 38 and 39 is formed. The pair of external electrodes 38 and 39 is formed in both end portions of the base substrate 2 in the longitudinal direction and is electrically connected to the pair of penetration electrodes 32 and 33, respectively.

When operating the piezoelectric vibrator 1 configured in this manner, a predetermined driving voltage is applied to the external electrodes 38 and 39 formed in the base substrate 2. As a result, since the voltage can be applied to the first excitation electrode 13 and the second excitation electrode 14 of the piezoelectric vibrating reed 4, it is possible to vibrate the pair of vibration arm portions 10 and 11 in a direction approaching and separating from each other at a predetermined frequency. Moreover, it is possible to use the vibration of the pair of vibration arm portions 10 and 11 as a time source, a timing source of the control signal, a reference signal source or the like.

### (Method of Manufacturing Piezoelectric Vibrator)

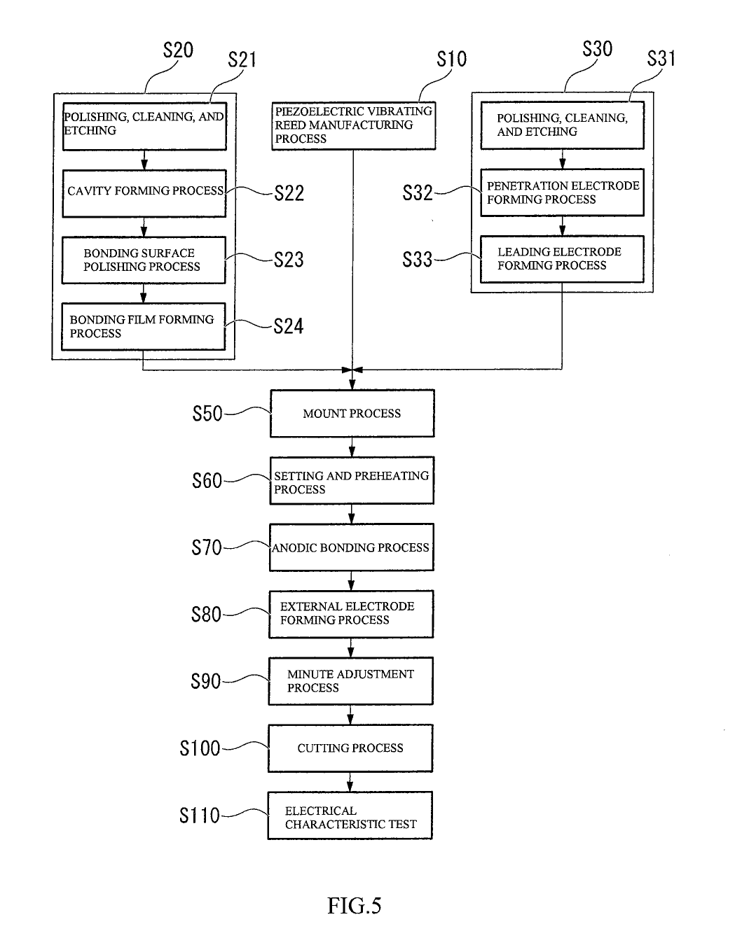

FIG. 5 is a flow chart of a method of manufacturing the piezoelectric vibrator 1 of the present embodiment,

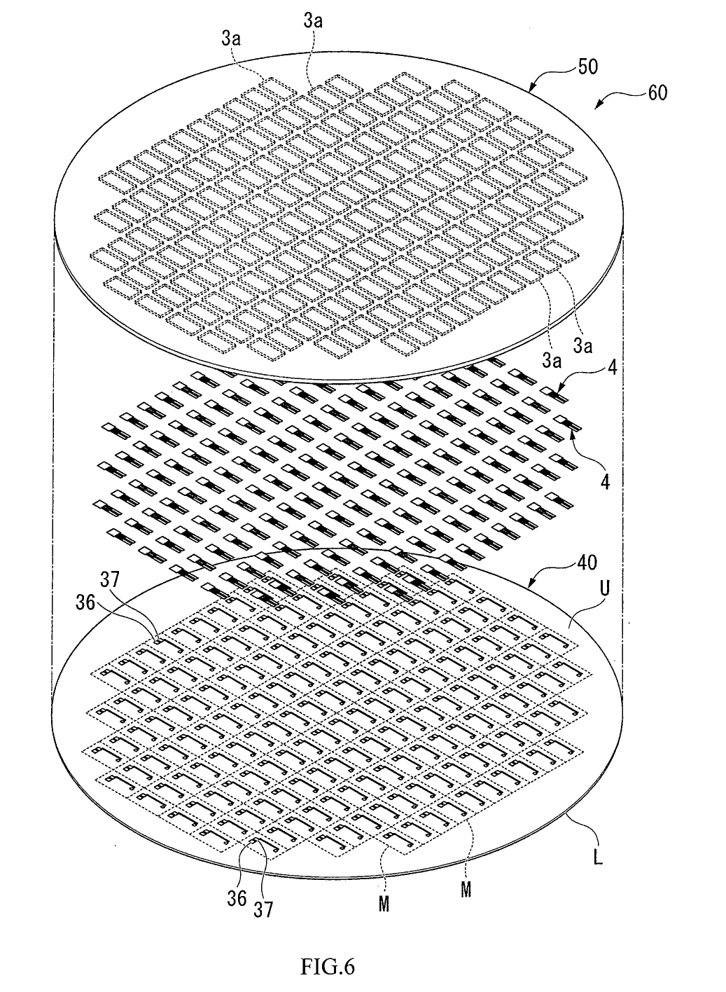

FIG. 6 is an exploded perspective view of a wafer body 60. In addition, a dashed-line shown in FIG. 6 shows a cutting line M that is cut in a cutting process to be performed later.

Next, a method of manufacturing the piezoelectric vibrator 1 will be described with reference to the flow chart of FIG. 5 and the drawings.

As shown in FIG. 5, the method of manufacturing the piezoelectric vibrator 1 according to the present embodiment mainly has a piezoelectric vibrating reed manufacturing process S10, a lead substrate wafer manufacturing process S20, a base substrate wafer manufacturing process S30, and an assembling process (after a mounting process S50). Among the respective processes, it is possible to combinedly perform the piezoelectric vibrating reed manufacturing process S10, the lead substrate wafer manufacturing process S20, and the base substrate wafer manufacturing process S30.

### (Piezoelectric Vibrating Reed Manufacturing Process S10)

In the piezoelectric vibrating reed manufacturing process S10, the piezoelectric vibrating reed 4 is manufactured. Specifically, firstly, Lambert ore of a crystal is sliced at a predetermined angle, and a mirror polishing such as polishing is performed to form a wafer of a predetermined thickness. Next, by performing the patterning to the exterior shape of the piezoelectric vibrating reed 4 by the use of the photolithography technique and performing the film formation and the patterning of the metal film, the excitation electrodes 13 and 14, the drawing electrodes 19 and 20, the mount electrodes 16 and 17, and the weight metal film 21 are formed. After that, the rough adjustment of the resonance frequency of the piezoelectric vibrating reed 4 is performed. In this manner, the piezoelectric vibrating reed manufacturing process S10 is finished.

### (Lead Substrate Wafer Manufacturing Process S20)

In the lead substrate wafer manufacturing process S20, as shown in FIG. 6, a lead substrate wafer 50 (corresponding to a “first substrate” of the claims) becoming the lead substrate 3 later is manufactured. Firstly, a disc-like lead substrate wafer 50 formed of a soda-lime glass is polished up to a predetermined thickness and cleaned, and then an affected layer of the uppermost surface is removed by the etching or the like (S21). Next, in a cavity forming process S22, a plurality of cavities 3a is formed on a bonding surface in the lead substrate wafer 50 with the base substrate wafer 40. The formation of the cavities 3a is performed by hot press molding, etching or the like. Next, in the bonding surface polishing process S23, a bonding surface with the base substrate wafer 40 is polished.

Next, in a bonding film forming process S24, on a bonding surface with the base substrate wafer 40 (corresponding to a “second substrate” of the claims), a bonding film 35 (see FIG. 3) formed of silicon is formed. The bonding film 35 may be formed on the overall inner surface of the cavity 3a, in addition to the bonding surface with the base substrate wafer 40. The formation of the bonding film 35 can be performed by a film forming method such as sputtering or CVD. In addition, since the bonding surface polishing process S23 is performed before the bonding film forming process S24, the flatness of the surface of the bonding film 35 is ensured, whereby it is possible to realize the stable bonding between the bonding film 35 and the base substrate wafer 40.

### (Base Substrate Wafer Manufacturing Process S30)

In the base substrate wafer manufacturing process S30, the base substrate wafer 40 becoming the base substrate 2 later is manufactured. Firstly, a disc-like base substrate wafer 40 formed of a soda-lime glass is polished up to a predetermined thickness and cleaned, and then an affected layer of the uppermost surface is removed by the etching or the like (S31).

### (Penetration Electrode Forming Process S32)

Next, a penetration electrode forming process S32 is performed which forms a pair of penetration electrodes 32 in the base substrate wafer 40. In addition, a formation process of the penetration electrode 32 will be described below, but the same is also true for the forming process of the penetration electrode 33.

Firstly, a penetration hole 30 is molded from the lower surface L to the upper surface U of the base substrate wafer 40 by press working or the like. Next, the metal pin 7 is inserted into the penetration hole 30 to fill the glass frit. The glass frit is mainly constituted by a powdered glass particle, an organic solvent, and a binder (a sticking agent).

Next, the glass frit is baked, and the glass barrel 6, the penetration hole 30, and the metal pin 7 (see FIG. 3) are integrated. For example, after transporting the base substrate wafer 40 to a baking furnace, the glass frit is baked. At this time, the organic solvent, the binder or the like in the glass frit are evaporated, and out gases such as carbon monoxide (CO), carbon dioxide (CO₂), and water vapor (H₂O) are generated and discharged to the outside of the glass frit.

Finally, by polishing the upper surface U and the lower surface L of the base substrate wafer 40 and making the metal pin 7 into a flat surface while being exposed to the upper surface U and the lower surface L, the penetration electrode 32 is formed in the penetration hole 30. By the penetration electrode 32, the conductivity of the upper surface U side and the lower surface L side of the base substrate wafer 40 is ensured, and the penetration hole 30 of the base substrate wafer 40 can be sealed.

### (Leading Electrode Forming Process S33)

Next, a leading electrode forming process S33 is performed which forms a plurality of leading electrodes 36 and 37 each electrically connected to the penetration electrodes on the upper surface U of the base substrate wafer 40. In addition, bumps B formed of gold or the like (see FIG. 4) are formed on the leading electrodes 36 and 37, respectively. In addition, in FIG. 6, in order to clarify the drawing, the bumps B are omitted. At this point of time, the base substrate wafer manufacturing process S30 is finished.

### (Mount Process S50)

Next, a mount process S50 is performed which bonds the piezoelectric vibrating reed 4 on the leading electrodes 36 and 37 of the base substrate wafer 40 via the bump B. Specifically, the base portion 12 of the piezoelectric vibrating reed 4 is placed on the bump B, and the ultrasonic wave vibration is applied while pressing the piezoelectric vibrating reed 4 to the bump B in the state of heating the bump B at a predetermined temperature. As a result, as shown in FIG. 3, the base portion 12 is mechanically fixed to the bump B in the state in which the vibration arm portions 10 and 11 of the piezoelectric vibrating reed 4 float from the upper surface U of the base substrate wafer 40 as shown in FIG. 3.

(Setting and preheating process S60)

Next, before the anodic bonding process S70, a setting and preheating process S60 is performed which sets the lead substrate wafer 50 and the base substrate wafer 40 on the anodic bonding apparatus and preliminarily heats the same. Hereinafter, firstly, a configuration of the anodic bonding apparatus will be described, and then the setting and preheating process S60 will be described.

(Anodic Bonding apparatus)

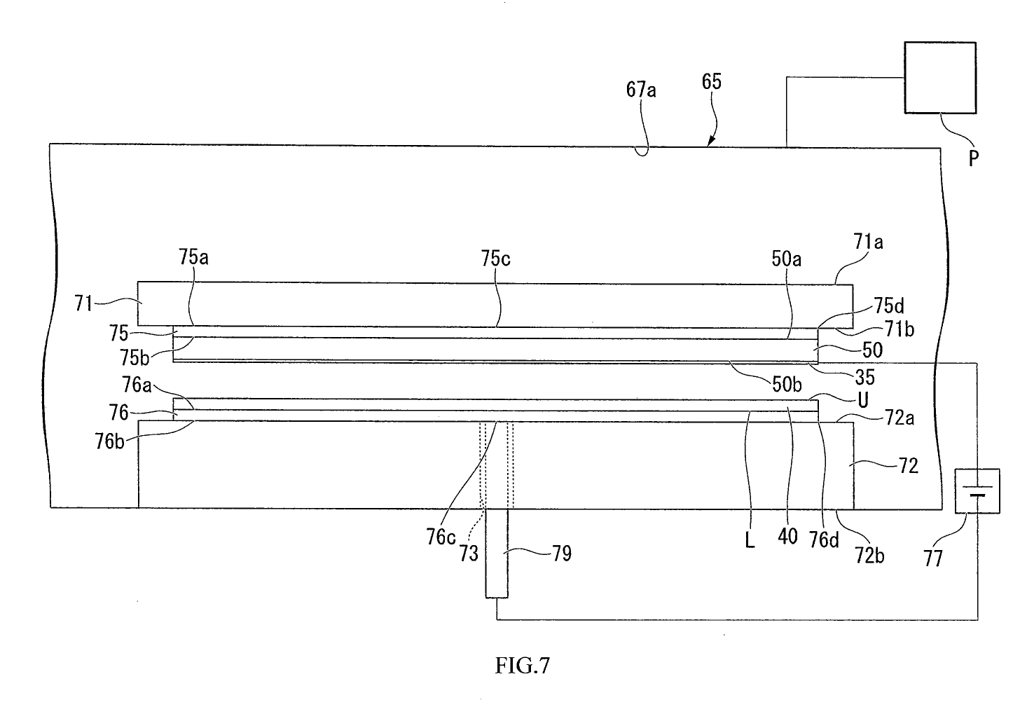

FIG. 7 is an explanatory diagram of an anodic bonding apparatus 65.

As shown in FIG. 7, the anodic bonding apparatus 65 is provided in a vacuum chamber 67a, and includes a first heater 71 disposed at an upper 50a (an outer surface) side of the lead substrate wafer 50, a second heater 72 disposed at a lower surface L (an outer surface) side of the base substrate wafer 40, a first intermediate member 75 disposed between the upper surface 50a of the lead substrate wafer 50 and the first heater 71, and a second intermediate member 76 disposed between the lower surface L of the base substrate wafer 40 and the second heater 72. In addition, in order to clarify the drawings, the thicknesses of the first intermediate member 75 and the second intermediate member 76 are represented in an exaggerated manner.

A vacuum pump P is connected to the vacuum chamber 67a, and the pressure in the vacuum chamber 67a can be controlled by the vacuum pump P. In the anodic bonding process S70, the anodic bonding is performed in a decompression atmosphere while performing evacuation by the vacuum pump P. Moreover, the out gas emitted from the base substrate wafer 40 and the lead substrate wafer 50 is discharged to the outside of the vacuum chamber 67a.

As the first heater 71 and the second heater 72, for example, a commercially available hot plate or the like is used. The first heater 71 and the second heater 72 have external shapes that are approximately the same as or greater than the base substrate wafer 40 and the lead substrate wafer 50 to be heated, whereby the first heater 71 and the second heater 72 can heat the entire surfaces of the upper surface 50a of the lead substrate wafer 50 and the lower surface L of the base substrate wafer 40.

Furthermore, in approximately the center of the second heater 72, a penetration hole 73 is formed through which an upper surface 72a (an inner surface) and a lower surface 72b (an outer surface) of the second heater 72 communicate with each other. A pin member 79 described later becoming a cathode during anodic bonding is inserted into the penetration hole 73.

The first intermediate member 75 disposed between the upper surface 50a of the lead substrate wafer 50 and the first heater 71 and the second intermediate member 76 disposed between the lower surface L of the base substrate wafer 40 and the second heater 72 are plate members having thicknesses of about 3.0 to 5.0 mm, respectively.

The first intermediate member 75 transfers heat from the first heater 71 to the lead substrate wafer 50. For this reason, the first intermediate member 75 is formed by porous carbon having high heat conductivity. Furthermore, the second intermediate member 76 transfers heat from the second heater 72 to the base substrate wafer 40, and ensures the earth by being connected to the pin member 79. For this reason, the second intermediate member 76 is formed by porous carbon having high conductivity and heat conductivity.

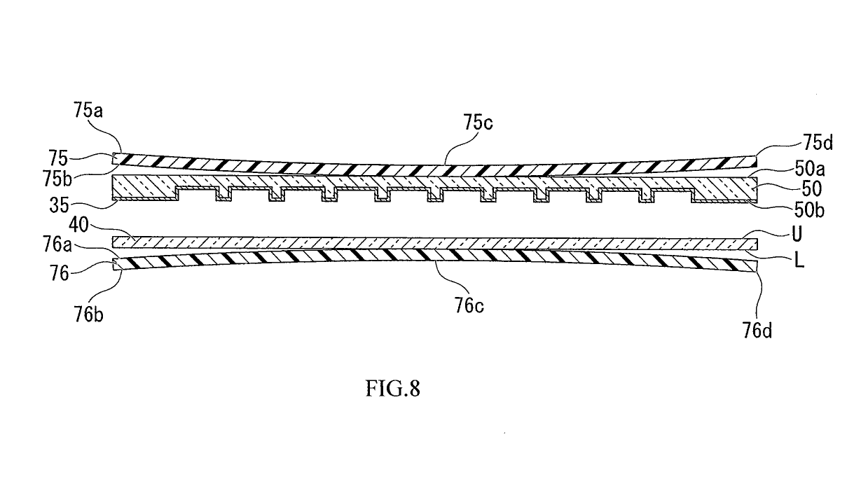

FIG. 8 is a cross-sectional view of the first intermediate member 75 and the second intermediate member 76 in the anodic bonding apparatus 65. In addition, in order to clarify the drawings, members other than the base substrate wafer 40, the lead substrate wafer 50, the first intermediate member 75, and the second intermediate member 76 are omitted.

As shown in FIG. 8, the central portion 75c of the first intermediate member 75 is formed so as to bulge to the lead substrate wafer 50 side further than the periphery portion 75d. Furthermore, the central portion 76c of the second intermediate member 76 is formed so as to bulge to the base substrate wafer 40 further than the periphery portion 76d. Thus, when setting the lead substrate wafer 50 on the anodic bonding apparatus 65, the vicinity of the center in the upper surface 50a of the lead substrate wafer 50 comes into contact with the central portion 75c in the lower surface 75b of the first intermediate member 75. Furthermore, when setting the base substrate wafer 40 on the anodic bonding apparatus 65, the vicinity of the center in the lower surface L of the base substrate wafer 40 comes into contact with the central portion 76c in the upper surface 76a of the second intermediate member 76.

The tip of the pin member 79 inserted into the penetration hole 73 formed in the center of the second heater 72 comes into contact with the central portion 76c in the lower surface 76b of the second intermediate member 76. The pin member 79 is an approximately cylindrical member and is formed by copper having excellent conductivity or the like. The length of the pin member 79 is formed to be sufficiently longer than the thickness of the second heater 72. The pin member 79 can press the base substrate wafer 40 toward the lead substrate wafer 50 via the second intermediate member 76 by a pressing device (not shown).

Furthermore, the pin member 79 is connected to a cathode of a power source 77 that applies the voltage during anodic bonding. That is, the pin member 79 has a function of a pressing pin that presses the base substrate wafer 40, and has a function as a cathode electrode of the power source 77. By bringing the tip of the pin member 79 into contact with the second intermediate member 76, the earth of the power source 77 is ensured.

In the setting and preheating process S60, the lead substrate wafer 50 and the base substrate wafer 40 are mounted and set on the anodic bonding apparatus 65. Moreover, the first heater 71 and the second heater 72 are preliminarily heated to discharge the out gas in advance.

As shown in FIG. 7, on the lower surface 71b of the first heater 71, the lead substrate wafer 50 is mounted via the first intermediate member 75 by a clamp jig (not shown). Furthermore, on the upper surface 72a of the second heater 72, the base substrate wafer 40 is mounted via the second intermediate member 76 by a clamp jig (not shown).

Next, in the state in which the lead substrate wafer 50 and the base substrate wafer 40 are separated from each other, the first heater 71 and the second heater 72 are preliminarily heated while evacuating the inner portion of the vacuum chamber 67a by the vacuum pump P. The preheating heats the first heater 71 and the second heater 72, for example, to become 350° C. to 450° C., evaporates the organic solvent, the binder, the moisture or the like remaining in the inner portion of the lead substrate wafer 50 and the base substrate wafer 40, and discharges the out gas such as carbon monoxide (CO), carbon dioxide (CO₂), and water vapor (H₂O) in advance. Moreover, after a predetermined time (for example, a time at which it is assumed that the out gas is discharged) elapses, the setting and preheating process S60 is finished.

### (Anodic Bonding Process S70)

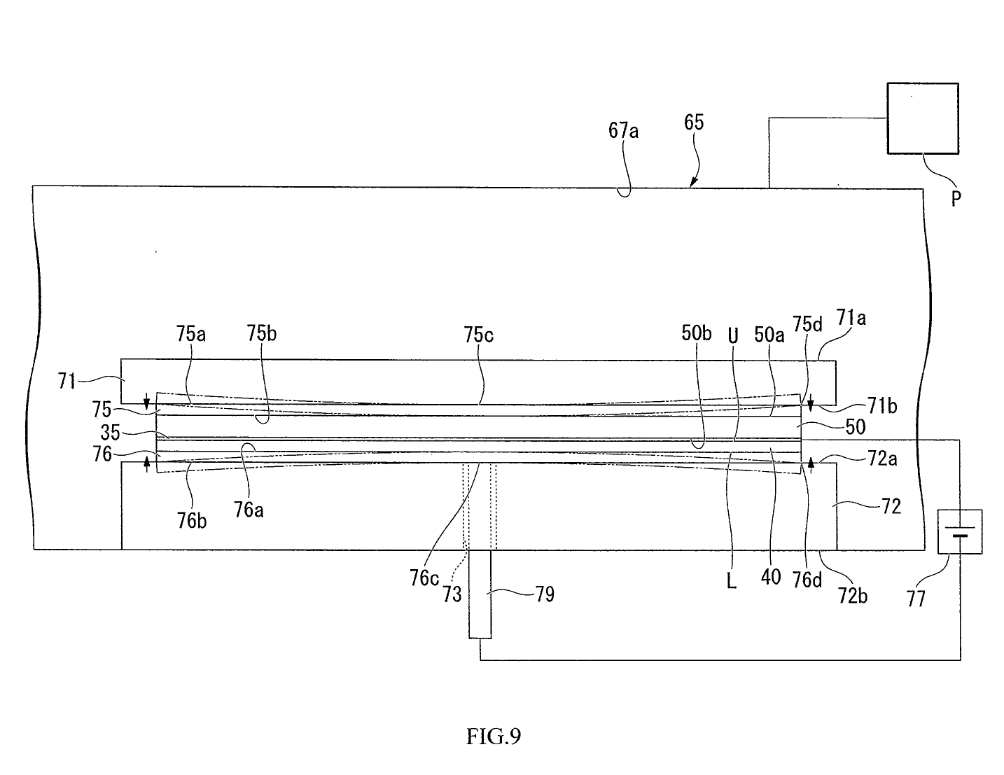

FIG. 9 is an explanatory diagram of an anodic bonding process S70.

Next, the anodic bonding process S70 is performed which anodically bonds the lead substrate wafer 50 and the base substrate wafer 40. Specifically, the anodic bonding is performed in the sequence as below.

The lead substrate wafer 50 is moved to the base substrate wafer 40 side (a lower side in FIG. 9) while evacuating the inner portion of the vacuum chamber 67a, thereby bringing the bonding film 35 of the lead substrate wafer 50 into contact with the upper surface U of the base substrate wafer 40.

Next, the upper surface 71a of the first heater 71 is pressed by a pressing device (not shown) to press the lead substrate wafer 50 against the base substrate wafer 40, and the central portion 76c in the lower surface 76b of the second intermediate member 76 is pressed by the pin member 79 to press the base substrate wafer 40 against the lead substrate wafer 50.

Next, the lead substrate wafer 50 is heated by the first heater 71 while being pressed by the pressing device and the pin member 79, and the base substrate wafer 40 is heated by the second heater 72. The first heater 71 and the second heater 72 are heated, for example, up to 200° C. to 300° C. that is the bonding temperature of the anodic bonding process S70.

Herein, since the lower surface 50b of the lead substrate wafer 50 and the upper surface U of the base substrate wafer 40 are anodic bonding surfaces, the surfaces are polished (see S23, S31 or the like).

For this reason, in the lower surface 50b and the upper surface 50a of the lead substrate wafer 50, the rough upper surface 50a has a surface area wider than the smooth lower surface 50b. Thus, when heating the lead substrate wafer 50 by the first heater 71, force attempting to dent and warp the lower surface 50b of the lead substrate wafer 50 is generated from a difference in amounts of expansion between the upper surface 50a and the lower surface 50b due to the heating.

Furthermore, similarly, even in regard to the base substrate wafer 40, in the upper surface U and the lower surface L of the base substrate wafer 40, the rough lower surface L has a surface area wider than the smooth upper surface U. Thus, when heating the base substrate wafer 40 by the second heater 72, force attempting to dent and warp the upper surface U of the base substrate wafer 40 is generated from a difference in amounts of expansion between the upper surface U and the lower surface L due to the heating.

However, the central portion 75c of the first intermediate member 75 bulges to the lead substrate wafer 50 side further than the periphery portion 75d. Furthermore, the central portion 76c of the second intermediate member 76 bulges to the base substrate wafer 40 side further than the periphery portion 76d. Moreover, the central portion 76c in the lower surface 76b of the second intermediate member 76 is pressed by the pin member 79, and the base substrate wafer 40 is pressed against the lead substrate wafer 50.

At this time, due to the pressing by the pressing device, the even deformation of the first intermediate member 75 and the second intermediate member 76 is promoted. In addition, due to the pressing by the pin member 79 and the reaction of the first intermediate member 75 and the second intermediate member 76 deformed evenly, a bonding load which prevents the warping of the base substrate wafer 40 and the lead substrate wafer 50 acts on the central portion of the lead substrate wafer 50 and the central portion of the base substrate wafer 40. Specifically, a bonding load acts which presses the central portion of the lead substrate wafer 50 toward the base substrate wafer 40 and presses the central portion of the base substrate wafer 40 toward the lead substrate wafer 50. As a result, during heating in the anodic bonding process S70, it is prevented that the warping is generated in the base substrate wafer 40 and the lead substrate wafer 50.

Next, while being heated by the first heater 71 and the second heater 72 in the state of being pressed by the pressing device and the pin member 79, the bonding film 35 of the lead substrate wafer 50 is connected to the anode electrode of the power source 77, the pin member 79 is connected to the cathode electrode of the power source 77, and a voltage of about 500 V is applied between the respective electrodes. In addition, at this time, the out gas not discharged in the setting and preheating process S60 and the out gas from the bonding film of silicon are generated.

Herein, as mentioned above, the bonding load acts on the central portion of the lead substrate wafer 50 and the central portion of the base substrate wafer 40, and the bonding load greater than the periphery portion of the lead substrate wafer 50 and the periphery portion of the base substrate wafer 40 acts thereon. For this reason, the central portion of the lead substrate wafer 50 and the central portion of the base substrate wafer 40 are firstly anodically bonded to each other.

In addition, upon being pressed by the pressing device and the pin member 79, the first intermediate member 75 and the second intermediate member 76 are evenly deformed so as to be expanded in a concentric circular shape, and the bonding load acts on the lower surface 50b of the lead substrate wafer 50 and the upper surface U of the base substrate wafer 40 so as to be expanded in the concentric circular shape.

In this manner, it is possible to sequentially perform the anodic bonding from the central portions of the lower surface 50b of the lead substrate wafer 50 and the upper surface U of the base substrate wafer 40 toward the periphery portions in the concentric circular shape. As a result, even when force attempting to dent and warp the lower surface 50b of the lead substrate wafer 50 and the upper surface U of the base substrate wafer 40 is generated, the anodic bonding can be performed while effectively discharging the out gas without sealing the out gas. Thus, it is possible to ensure a satisfactory degree of vacuum in the piezoelectric vibrator 1.

### (External Electrode Forming Process S80)

Next, an external electrode forming process S80 is performed which patterns the conductive material on the lower surface L of the base substrate wafer 40 and forms a plurality of pairs of external electrodes 38 and 39 (see FIG. 3) electrically connected to the pair of penetration electrodes 32 and 33, respectively. By the process, the piezoelectric vibrating reed 4 communicates with the external electrodes 38 and 39 through the penetration electrodes 32 and 33.

### (Minute Adjustment Process S90)

Next, a minute adjustment process S90 is performed which minutely adjusts the frequencies of the individual piezoelectric vibrators sealed in the cavity 3a and puts the same in a predetermined range in the state of the wafer body 60. Specifically, the predetermined voltage is consecutively applied from the external electrodes 38 and 39 shown in FIG. 3, and the frequency is measured by vibrating the piezoelectric vibrating reed 4. In this state, laser light is irradiated from the outside of the base substrate wafer 40, thereby evaporating the minute adjustment film 21b (see FIG. 2) of the weight metal film 21. As a result, since the weight of the tip sides of the pair of vibration arm portions 10 and 11 drops, the frequency of the piezoelectric vibrating reed 4 rises. As a result, it is possible to minutely adjust the frequency of the piezoelectric vibrator and put the same in the range of the nominal frequency.

### (Cutting Process S100)

After the minute adjustment of the frequency is finished, a cutting process S100 is performed which cuts the bonded wafer body 60 along the cutting line M shown in FIG. 6. Specifically, a UV tape is glued to the surface of the base substrate wafer 40 of the wafer body 60. Next, a laser is irradiated from the lead substrate wafer 50 side along the cutting line M (scribe). Next, a cutting edge is pressed from the surface of the UV tape along the cutting line M to cleave the wafer body 60 (braking). After that, UV light is irradiated to peel off the UV tape. As a result, the wafer body 60 can be divided into a plurality of piezoelectric vibrators 1. In addition, the wafer body 60 may be cut by another method such as dicing.

In addition, a process sequence may be adopted in which, after performing the cutting process S100 to form individual piezoelectric vibrators, the minute adjustment process S90 is performed. However, as mentioned above, since the minute adjustment can be performed in the state of the wafer body 60 by performing the minute adjustment process S90 in advance, a plurality of piezoelectric vibrators can more effectively and minutely adjusted. Thus, it is desirable since an improvement in throughput can be promoted.

### (Electrical Characteristic Test S110)

After that, internal electrical characteristic test S110 is performed. That is, the resonance frequency or the resonance resistance value of the piezoelectric vibrating reed 4, the drive level characteristic (the excitation electric power dependency of the resonance frequency and the resonance resistance value) or the like are measured and checked. Furthermore, the insulation resistance characteristic or the like is checked as well. Moreover, finally, an appearance test of the piezoelectric vibrator is performed, and the size, the quality or the like are finally checked. The manufacturing of the piezoelectric vibrator is finished by this.

### (Effects)

According to the present embodiment, since the first intermediate member 75 is configured so that the central portion 75c bulges toward the base substrate wafer 40 further than the periphery portion 75d and the second intermediate member 76 is configured so that the central portion 76c bulges toward the lead substrate wafer 50 further than the periphery portion 76d, immediately after the anodic bonding is started, it is possible to cause the bonding load to act in the central portion of the base substrate wafer 40 and the lead substrate wafer 50, thereby anodically bonding the central portion in advance. Furthermore, since the first intermediate member 75 and the second intermediate member 76 are evenly deformed during anodic bonding, after anodically bonding the central portion of the base substrate wafer 40 and the lead substrate wafer 50, it is possible to sequentially perform the anodic bonding in the concentric circular shape toward the peripheries of the base substrate wafer 40 and the lead substrate wafer 50. As a result, even when force attempting to dent and warp the inner surface is generated in the base substrate wafer 40 and the lead substrate wafer 50, it is possible to perform the anodic bonding while effectively discharging the out gas without sealing the out gas. Thus, it is possible to ensure a satisfactory degree of vacuum in the package 9.

Furthermore, according to the present embodiment, since the first intermediate member 75 and the second intermediate member 76 is formed of carbon and can ensure excellent conductivity and heat conductivity, the anodic bonding can reliably be performed. Furthermore, by forming the first intermediate member 75 and the second intermediate member 76 in a porous shape, during anodic bonding, the first intermediate member 75 and the second intermediate member 76 can reliably and evenly be deformed. Thus, it is possible to cause the bonding load to act in the entire inner surface of the base substrate wafer 40 and the lead substrate wafer 50 to reliably perform the anodic bonding.

Furthermore, according to the present embodiment, by forming the bonding film 35 by silicon, it is possible to form the package 9 having excellent corrosion resistance. Furthermore, since the out gas can effectively be discharged during anodic bonding, the present invention is preferable when forming the bonding film 35 by silicon which generates gas during anodic bonding.

Furthermore, according to the present embodiment, by pressing the second intermediate member 76 by the pin member 79 from the lower surface 76b side (the outer surface side) toward the upper surface 76a side (the inner surface side), it is possible to cause the great bonding load to act on the central portions of the first substrate and the second substrate to perform the anodic bonding. Thus, after anodically bonding the central portions of the base substrate wafer 40 and the lead substrate wafer 50, it is possible to reliably and sequentially perform the anodic bonding toward the periphery portions of the base substrate wafer 40 and the lead substrate wafer 50. As a result, even when force attempting to dent and warp the inner surface is generated in the base substrate wafer 40 and the lead substrate wafer 50, it is possible to reliably perform the anodic bonding while effectively discharging the out gas without sealing the out gas. Thus, it is possible to ensure a more satisfactory degree of vacuum in the package 9.

Furthermore, according to the present embodiment, since the piezoelectric vibrating reed 4 is sealed in the inner portion of the package 9 that is manufactured by the method of manufacturing the package capable of ensuring the satisfactory degree of vacuum, it is possible to provide the piezoelectric vibrator 1 that has a low equivalent resistance value and excellent electrical characteristics.

### (Oscillator)

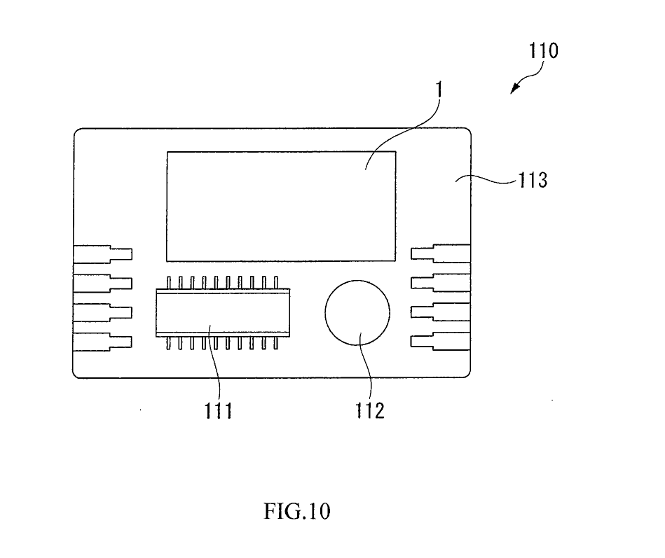

Next, an embodiment of an oscillator according to the present invention will be described with reference to FIG. 10.

As shown in FIG. 10, the oscillator 110 of the present embodiment is configured as an oscillating element in which the piezoelectric vibrator 1 is electrically connected to an integrated circuit 111. The oscillator 110 includes a substrate 113 with an electronic element component 112 such as a condenser mounted thereon. The integrated circuit 111 for the oscillator is mounted on the substrate 113, and the piezoelectric vibrating reed of the piezoelectric vibrator 1 is mounted near the integrated circuit 111. The electronic element component 112, the integrated circuit 111, and the piezoelectric vibrator 1 are electrically connected to each other by a wiring pattern (not shown), respectively. In addition, the respective components are molded by resin (not shown).

In the oscillator 110 configured in this manner, upon applying the voltage to the piezoelectric vibrator 1, the piezoelectric vibrating reed in the piezoelectric vibrator 1 is vibrated. The vibration is converted to the electric signal by the piezoelectric characteristics of the piezoelectric vibrating reed, and is input to the integrated circuit 111 as the electric signal. The input electric signal is subjected to the various processes by the integrated circuit 111 and is output as the frequency signal. As a result, the piezoelectric vibrator 1 functions as the oscillating element.

Furthermore, by selectively setting the RTC (real time clock) module or the like depending on the demand, the configuration of the integrated circuit 111 can be added with functions of controlling the operation date or the time of the device or an external device or providing the time, the calendar or the like in addition to a single-function oscillator for the timepiece.

According to the oscillator 110 of the present embodiment, since the piezoelectric vibrator 1 having a low equivalent resistance value and excellent electrical characteristics is included, the oscillator 110 of high performance can be provided.

(Electronic apparatus)

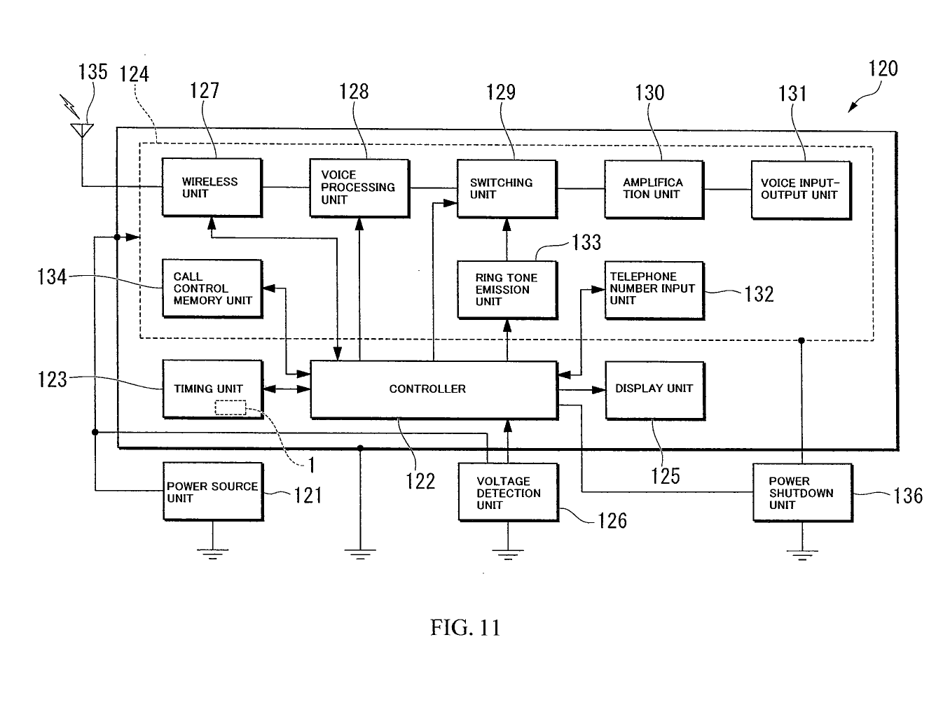

Next, an embodiment of an electronic apparatus according to the present invention will be described with reference to FIG. 11. Furthermore, a portable information device 120 having the piezoelectric vibrator 1 mentioned above as the electronic apparatus will be described as an example.

Firstly, the portable information device 120 of the present embodiment is represented by, for example, a mobile phone, and is a device in which a wrist watch in the related art is developed and improved. The appearance thereof is similar to that of a wrist watch, a liquid crystal display is disposed in a portion corresponding to a dial face, and the current time or the like can displayed on the screen. Furthermore, in the case of being used as a communicator, the portable information device is removed from the wrist, and it is possible to perform the communication like the mobile phone of the related art using a speaker and a microphone equipped in the inner portion of the band. However, the portable information device is considerably reduced in size and weight compared to the mobile phone of the related art.

Next, a configuration of the portable information device 120 of the present embodiment will be described. As shown in FIG. 11, the portable information device 120 includes the piezoelectric vibrator 1 and a power source portion 121 for supplying the electric power. The power source portion 121 is formed by, for example, a lithium secondary battery. In the power source portion 121, a control portion 122 which performs the various controls, a count portion 123 which performs the count of the time or the like, a communication portion 124 that performs the communication with the outside, a display portion 125 that displays various pieces of information, and a voltage detection portion 126 that detects the voltages of the respective functional portions are connected to each other in parallel. Moreover, the respective functional portions are supplied with the electric power by the power source portion 121.

The control portion 122 controls the respective functional portions and performs the operation control of the whole system such as the transmission and the reception of the voice data, and the measurement and display of the current time. Furthermore, the control portion 122 includes a ROM on which program is written in advance, a CPU which reads and executes the program written on the ROM, a RAM that is used as a work area of the CPU or the like.

The count portion 123 includes an integrated circuit equipped with an oscillation circuit, a register circuit, a counter circuit, an interface circuit or the like, and the piezoelectric vibrator 1. When applying the voltage to the piezoelectric vibrator 1, the piezoelectric vibrating reed is vibrated, and the vibration is converted to the electric signal by the piezoelectric characteristics of crystal and is input to the oscillation circuit as the electric signal. The output of the oscillation circuit is binarized and is counted by the register circuit and the counter circuit. Moreover, the signal is transmitted to and received from the control portion 122 via the interface circuit, and the current time, the current date, the calendar information or the like are displayed on the display portion 125.

The communication portion 124 has the same function as a mobile phone of the related art, and includes a wireless portion 127, a voice process portion 128, a switching portion 129, an amplification portion 130, a voice input and output portion 131, a phone number input portion 132, a ringtone generating portion 133, and a call control memory portion 134.

The wireless portion 127 performs an exchange of the transmission and the reception with the base station via an antenna 135 on various data such as the voice data. The voice process portion 128 encodes and decodes the voice signal that is input from the wireless portion 127 or the amplification portion 130. The amplification portion 130 amplifies the signal, which is input from the voice process portion 128 or the voice input and output portion 131, up to a predetermined level. The voice input and output portion 131 is constituted by a speaker, a microphone or the like, heightens the ringtone or the received voice, or collects the voice.

Furthermore, the ringtone generating portion 133 creates the received voice depending on the voice from the base station. The switching portion 129 switches the amplification portion 130 connected to the voice process portion 128 into the ringtone generating portion 133 only at the time of the reception, whereby the ringtone created in the ringtone generating portion 133 is output to the voice input and output portion 131 via the amplification portion 130.

In addition, the call control memory portion 134 stores the program relating to the call arrival and departure control of the communication. Furthermore, the phone number input portion 132 includes, for example, number keys from 0 to 9, and other keys, and a phone number or the like of a communication target is input by pressing the number keys or the like.

When the voltage added to the respective functional portions such as the control portion 122 by the power source portion 121 is lower than a predetermined value, the voltage detection portion 126 detects the voltage drop and provides notification of the same to the control portion 122. The predetermined voltage value of this time is a value which is set as a minimum voltage required for stably operating the communication portion 124 in advance, and, for example, is about 3V. The control portion 122 received the notification of the voltage drop from the voltage detection portion 126 prevents the operations of the wireless portion 127, the voice process portion 128, the switching portion 129, and the ringtone generating portion 133. Particularly, the operation stop of the wireless portion 127 having high power consumption is essential. In addition, an indication is displayed on the display portion 125 to the effect that the communication portion 124 is unusable due to the shortage of the remaining battery amount.

That is, the operation of the communication portion 124 is prohibited by the voltage detection portion 126 and the control portion 122, and the indication thereof can be displayed on the display portion 125. The display may be a text message, but an X (false) mark may be displayed on a phone icon displayed on the upper portion of the display surface of the display portion 125 as a more intuitive display.

In addition, a power source blocking portion 136 capable of selectively cutting the power source of a portion relating to the function of the communication portion 124 is included, whereby the function of the communication portion 124 can more reliably be stopped.

According to the portable information device 120 of the present embodiment, since the piezoelectric vibrator 1 having a low equivalent resistance and excellent electrical characteristics is included, the portable information device 120 of high performance can be provided.

### (Radio Timepiece)

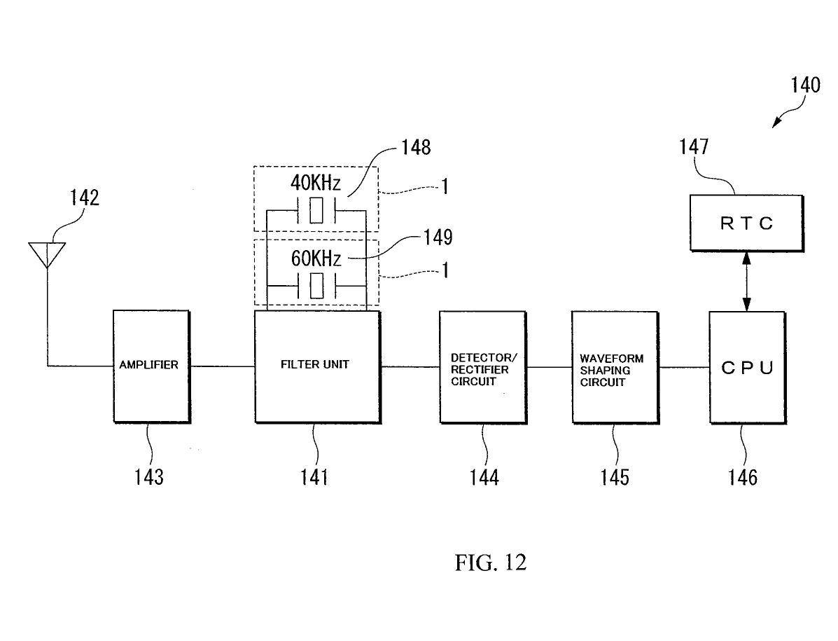

Next, an embodiment of a radio timepiece according to the present invention will be described with reference to FIG. 12.

As shown in FIG. 12, the radio timepiece 140 of the present embodiment includes the piezoelectric vibrator 1 that is electrically connected to a filter portion 141, and is a timepiece that has a function of receiving a standard radio wave including the timepiece information and automatically correcting and displaying the same at a correct time.

In Japan, in Fukushima-ken (40 kHz) and Saga-ken (60 kHz), transmission stations (transmission departments) transmitting the standard radio wave are present and transmit standard radio waves, respectively. Long waves such as 40 kHz or 60 kHz have both a nature of being diffused through the surface of earth and a nature of being diffused while being reflected by an ionization layer and the surface of earth, the diffusion range is wide, and two transmission stations cover all Japan.

Hereinafter, a functional configuration of the radio timepiece 140 will specifically be described.

An antenna 142 receives the standard radio wave of a long wave of 40 kHz or 60 kHz. The standard radio wave of the long wave is a radio wave in which an AM modulation of the time information called a time code is performed on the carrier wave of 40 kHz or 60 KHz. The received standard radio wave of the long wave is amplified by an amplifier 143, and is filtered and tuned by a filter portion 141 having a plurality of piezoelectric vibrators 1.

The piezoelectric vibrator 1 in the present embodiment includes crystal vibrator portions 148 and 149 having the same resonance frequency of 40 kHz and 60 kHz as the carrier frequency mentioned above, respectively.

In addition, the filtered signal of a predetermined frequency is detected and demodulated by a detection and rectifier circuit 144.

Next, the time code is taken out via a waveform shaping circuit 145 and is counted by the CPU 146. In the CPU 146, information such as a current year, an integration date, a day of week, and a time are read. The read information is reflected on the RTC 148 and the correct time information is displayed.

Since the carrier wave is 40 kHz or 60 kHz, as the crystal vibration portions 148 and 149, a vibrator having the tuning fork-like structure mentioned above is preferable.

In addition, the description mentioned above is indicated as an example in Japan, but the frequency of the standard radio wave of the long wave differs in abroad. For example, a standard radio wave of 77.5 kHz is used in Germany. Thus, when a radio timepiece 140 capable of responding even when abroad is built in the portable device, there is a need for a piezoelectric vibrator 1 which has a frequency different from the case of Japan.

According to the radio timepiece 140 of the present embodiment, since the piezoelectric vibrator 1 having a low equivalent resistance value and excellent electrical characteristics is included, a radio timepiece 140 of high performance can be provided.

In addition, the present invention is not limited to the embodiment mentioned above.

In the present embodiment, the tuning fork-type piezoelectric vibrating reed 4 is sealed in the inner portion of the package 9 to manufacture the piezoelectric vibrator 1, while using the method of manufacturing the anodic bonding apparatus 65 and the package 9 according to the present invention. However, for example, an AT cut type piezoelectric vibrating reed (a thickness-shear vibrating reed) may be sealed in the inner portion of the package 9 to manufacture the piezoelectric vibrator. Furthermore, an electronic component other than the piezoelectric vibrating reed may be sealed in the inner portion of the package 9 to manufacture an electronic apparatus other than the piezoelectric vibrator.

In an anodic bonding process S70 of the present embodiment, the pin member 79 is connected to the cathode of the power source 77, and the earth of the power source 77 is ensured by bringing the tip of the pin member 79 into contact with the second intermediate member 76. However, the cathode of the power source 77 may directly be connected to the second heater 72 to ensure the earth of the power source 77.

In the present embodiment, as the materials of the first intermediate member 75 and the second intermediate member 76, porous carbon is selected. However, the material of the first intermediate member 75 and the second intermediate member 76 may be a material having the conductivity and the heat conductivity without being limited to the porous carbon.

In the present embodiment, as the material of the bonding material of the first intermediate member 75 and the second intermediate member 76, silicon was selected. However, the material of the bonding material is not limited to silicon, but, for example, may be metal such as aluminum or chrome. From the viewpoint of the corrosion resistance, silicon is preferably used in the bonding material, and the present invention is preferable when silicon generating the gas during anodic bonding is used as the bonding material.

What is claimed is:

1. An anodic bonding apparatus for manufacturing a package by anodically bonding an inner surface of a first substrate and an inner surface of a second substrate via a bonding material, the apparatus comprising:
a first heater that is disposed at an outer surface side of the first substrate and presses the first substrate during anodic bonding;
a second heater that is disposed at an outer surface side of the second substrate and presses the second substrate during anodic bonding;
a first intermediate member that is disposed between the outer surface of the first substrate and the first heater, has heat conductivity, and can be flexible; and
a second intermediate member that is disposed between the outer surface of the second substrate and the second heater, has conductivity and heat conductivity, and can be flexible,
wherein the first intermediate member is formed so that a central portion thereof bulges toward the second substrate further than a periphery portion thereof, and the second intermediate member is formed so that a central portion thereof bulges toward the first substrate further than a periphery portion thereof, and
as the respective heaters press the corresponding substrates, respectively, the respective intermediate members are evenly deformed.

2. The anodic bonding apparatus according to claim 1,
wherein the first intermediate member and the second intermediate member are formed of porous carbon.

3. The anodic bonding apparatus according to claim 1,
wherein the bonding material is silicon.

4. The anodic bonding apparatus according to claim 1,
wherein, in the middle of the second heater, a penetration hole is formed through which the inner surface and the outer surface of the second heater communicate with each other, and
a pin member is inserted into the penetration hole so as to press the second intermediate member from the outer surface side toward the inner surface side during anodic bonding.

5. A method of manufacturing a package by the use of the anodic bonding apparatus according to claim 1, the method comprising:
a setting and preheating process of setting the first substrate on the first heater via the first intermediate member, setting the second substrate on the second heater via the second intermediate member, and preliminarily heating the first substrate and the second substrate; and
an anodic bonding process of pressing the first intermediate member toward the second substrate, pressing the second intermediate member toward the first substrate, evenly deforming the first intermediate member and the second intermediate member, and bonding the first substrate and the second substrate.

6. A piezoelectric vibrator in which a piezoelectric vibrating reed is sealed in an inner portion of the package manufactured by the method of manufacturing the package according to claim 5.

7. An oscillator in which the piezoelectric vibrator according to claim 6 is electrically connected to an integrated circuit as an oscillating element.

8. An electronic apparatus in which the piezoelectric vibrator according to claim 6 is electrically connected to a count portion.

9. A radio timepiece in which the piezoelectric vibrator according to claim 6 is electrically connected to a filter portion.
